(19) United States
(12) Patent Application Publication
(10) Pub. No.: US 2026/0186019 A1
(43) Pub. Date: Jul. 2, 2026

(54) INTEGRATED CIRCUIT (IC) CHIP TEST SOCKET ASSEMBLIES WITH SPRING PROBES THAT SCRUB IC PACKAGE ELECTRICAL CONTACT PADS

(71) Applicant: Smiths Interconnect Americas, Inc., Kansas City, MO (US)

(72) Inventors: Jiachun ZHOU, Gilbert, AZ (US); Zhixia ZHU, Jiangsu, Jiangsu (CN)

(21) Appl. No.: 19/116,582

(22) PCT Filed: Sep. 26, 2023
(86) PCT No.: PCT/US2023/075132

§ 371 Date: Mar. 28, 2025

(30) Foreign Application Priority Data
Sep. 29, 2022 (CN) 202211201313.4

(51) Int. Cl. G01R 1/04; G01R 3/00

(52) U.S. Cl. CPC G01R 1/0466; G01R 3/00

(57) ABSTRACT

In one aspect, a socket assembly for testing an integrated circuit (IC) of an IC package is provided. The socket assembly includes a main body. The main body includes a first surface and a second surface opposing the first surface, and the main body defines a cavity that extends between the first surface and the second surface. The cavity is sized to receive a spring probe therein, and the main body further defines an opening at the first surface for the cavity that is offset relative to a centerline of the cavity.

### CROSS-REFERENCE TO RELATED APPLICATIONS

This application claims priority to Chinese Patent Application No. 202211201313.4, filed 29 Sep. 2022, entitled INTEGRATED CIRCUIT (IC) CHIP TEST SOCKET ASSEMBLIES WITH SPRING PROBES THAT SCRUB IC PACKAGE ELECTRICAL CONTACT PADS, the entire contents of which are hereby incorporated by reference.

### BACKGROUND

The field of the disclosure relates to test sockets for integrated circuit packages, and more particularly, to test sockets that utilize spring probes that contact substantially flat pads on the integrated circuit packages.

An integrated circuit (IC) is a set of electronic circuits fabricated on a flat substate, or chip, of semiconductor material such as silicon. Production of ICs generally includes testing of the ICs in a manner that simulates an end-user's application of those ICs. One manner of testing ICs is to connect each IC through a test socket assembly to a printed circuit board (PCB), or load board, that exercises various functionalities of the IC. The test socket assembly can be re-used to test many ICs.

Land grid array (LGA) and quad flat no-lead packages (QFN) are two common packages for semiconductor ICs. LGA and QFN packages use substantially flat electrically conductive pads on the bottom surface of the package that are electrically connected to the IC within the package (e.g., using wire bonds or other types of contact methods, such as flip chip bonding the IC to a substrate of the IC package). Test sockets for LGA and QFN packages typically include spring probes that contact the pads on the underside of the IC package as the IC package is held in place in the test socket. However, oxidation of the pads on the IC package may cause poor electrical connections between the pads on the IC package and the spring probes in the test socket, which can distort the results of the tests being performed on the IC(s) in the IC package.

Thus, it is desirable to improve test sockets to more reliably test IC packages that utilize substantially flat electrically conductive pads, such as LGA and QFN packages.

### BRIEF DESCRIPTION

In one aspect, a socket assembly for testing an IC of an IC package is provided. The socket assembly includes a main body. The main body includes a first surface and a second surface opposing the first surface, and the main body defines a cavity that extends between the first surface and the second surface. The cavity is sized to receive a spring probe therein, and the main body further defines an opening at the first surface for the cavity that is offset relative to a centerline of the cavity.

In another aspect, a method of assembling a socket assembly for testing an IC of an IC package is provided. The method includes forming a main body that includes a first surface and a second surface opposing the first surface. The main body defines a cavity that extends between the first surface and the second surface. The cavity is sized to receive a spring probe therein, and the main body further defines an opening at the first surface for the cavity that is offset relative to a centerline of the cavity.

In another aspect, a socket assembly for testing an IC of an IC package is provided. The socket assembly includes a plurality of spring probes and a main body. Each of the plurality of spring probes includes a tapered portion and a contact tip. The main body includes a first surface and a second surface opposing the first surface. The main body defines a plurality of cavities that extend between the first surface and the second surface, and each of the plurality of cavities is sized to receive one of the spring probes therein. The main body further defines an offset hole at the first surface for each of the plurality of cavities, and the tapered portion and the contact tip for each of the plurality of spring probes extend through the offset hole away from the first surface.

### DRAWINGS

These and other features, aspects, and advantages of the present disclosure will become better understood when the following detailed description is read with reference to the accompanying drawings in which like characters represent like parts throughout the drawings, wherein:

FIG. 1 depicts a perspective view of an IC test system in an example embodiment.

FIG. 2 depicts a perspective view of a socket assembly for the IC test system of FIG. 1 in an example embodiment.

FIGS. 3A and 3B depict cross-sectional views of a region of the socket assembly of FIG. 2 along cut lines 2-2 in example embodiments.

FIGS. 4A and 4B depict cross-sectional views of the region of the socket assembly of FIG. 2 along cut lines 2-2 in example embodiments.

FIG. 5 depicts a block diagram of another IC test system in an example embodiment.

FIG. 6 depicts a block diagram of another IC test system in an example embodiment.

FIG. 7 depicts a flow chart of a method of assembling a socket assembly for testing an IC of an IC package in an example embodiment.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

In testing ICs, a fundamental component of a test system that enables testing of the ICs is a test socket assembly for the IC package that can be re-used many times to test large quantities of the ICs. The test socket assembly connects, both electrically and mechanically, the IC package to a printed circuit board (PCB) or a load board. The degree to which the test socket assembly can be re-used is quantified by how many “cycles” it can withstand without degrading performance, e.g., signal performance. Each time an IC package is inserted, or set, into the test socket assembly is referred to as one cycle. Generally, over the course of many cycles, the electrical and mechanical properties of the contacts and structures of the test socket assembly begin to degrade.

As discussed previously, a test socket for IC packages that utilize substantially flat electrically conductive pads can fail to adequately provide a reliable electrical contact between the spring probes in the test socket and the pads on the IC package, due to oxidation of the pads. Accordingly, the test results may be distorted, and the IC under test may fail the testing process for reasons outside of the actual performance of the IC itself.

In the embodiments described herein, a test socket assembly is described that includes spring probes having a contact tip that contacts pads on the IC package. When the IC package is inserted into the test socket assembly, the spring probes are compressed by the pads on the IC package, and the contact tips of the spring probes moves substantially parallel or substantially lateral with respect to the major plane of the pads. The movement of the contact tips of the spring probes scrubs a portion of the pads on the IC package, which removes oxidation from the pads and ensures a reliable electrical connection between the contact tips of the spring probes and the pads.

Although movement of the contact tips of the spring probes substantially parallel to the major plane of the pad may be generated in a number of different ways, one embodiment describes a main body of the test socket assembly that defines cavities with offset holes, with spring probes disposed therein. A top plunger of a spring probe within a cavity extends through the offset hole and away from a major surface of the main body. When the IC package is inserted into the test socket, pads on the IC package engage with contact tips on the spring probes, compressing the spring probes to reduce the length of the spring probes. The top plunger has a taper that decreases from a position proximate to the contact tip of the top plunger towards a shoulder of a shell of the spring probe, which abuts to the offset hole within the cavity. As the top plunger is compressed by a pad on the IC package, the offset hole and the taper in the top plunger generate a lateral movement in the contact tip with respect to the pad, which moves the contact tip of the top plunger across a portion of the pad on the IC package. This movement removes oxidation from the pad and exposes the electrically conductive features of the pad to the contact tip of the spring probe.

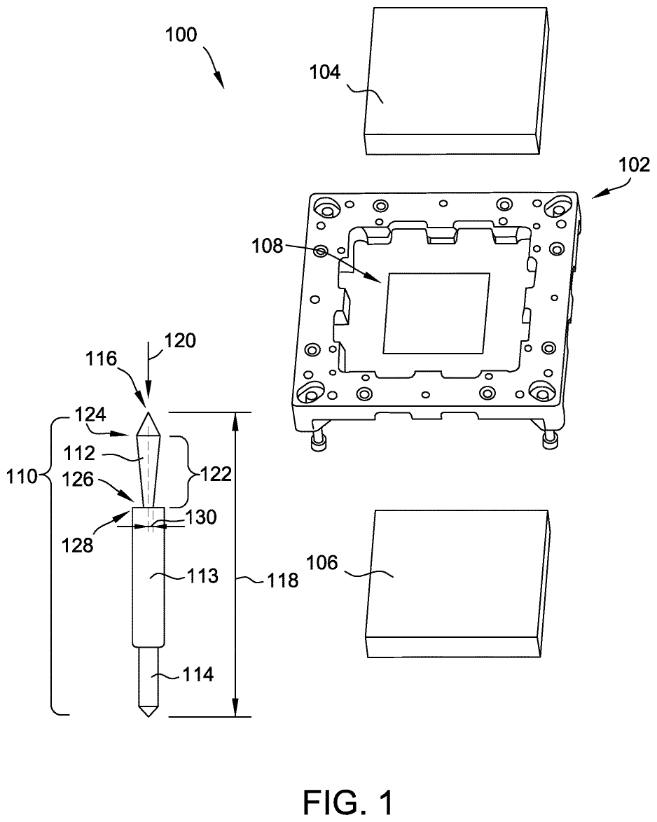

FIG. 1 depicts a perspective view of an IC test system 100 in an example embodiment. In this embodiment, IC test system 100 includes a socket assembly 102, a semiconductor IC package 104, and a PCB 106. IC package 104 is a device to be tested. IC package 104 may include any type of package that utilizes substantially flat electrical contact pads (e.g., LGA packages, QFN packages, etc.) along a major surface (e.g., the underside of the IC package). The pads may be formed form various electrically conductive materials, including but not limited to tin, copper, and/or gold, and alloys of tin, copper, and/or gold.

In this embodiment, PCB 106 includes test circuits (not shown), that operate to perform tests on the ICs (not shown) within IC package 104 while IC package 104 is loaded into an opening 108 of socket assembly 102. Socket assembly 102 provides electrical and mechanical connections between IC package 104 and PCB 106. In this embodiment, IC test system 100 further include a plurality of spring probes 110.

During assembly of socket assembly 102, spring probes 110 are placed in cavities (not shown) in socket assembly 102 that are exposed by opening 108, and spring probes 110 are used to establish electrical connections between the pads of IC package 104 and PCB 106. Specifically, spring probes 110 may be connected to one or more grounds of PCB 106, one or more power supplies of PCB 106, and various signals generated by the test circuits (not shown) of PCB 106.

In operation, socket assembly 102 is mounted on PCB 106. To test IC package 104, IC package 104 is placed into opening 108 of socket assembly 102 and the test circuits of PCB 106 are operated to perform tests on the IC(s) within IC package 104 using power, ground, and signals transmitted between PCB 106 and the pads of IC package 104 via spring probes 110.

In this embodiment, spring probes 110 include a top plunger 112, a shell 113, a spring (not shown) within shell 113, and a bottom plunger 114. A contact tip 116 is located at a distal end of top plunger 112. Spring probes 110 are installed in cavities (not shown) in socket assembly 102 that are exposed by opening 108 and contact tip 116 contacts the electrically conductive pads (not shown) in IC package 104 when IC package 104 is inserted into opening 108. Spring probes 110 have a length 118 that decreases as a force 120 is applied to contact tip 116 by the pads on IC package 104. When force 120 is applied to contact tip 116, length 118 of spring probe 110 decreases as top plunger 112 and shell 113 slide over bottom plunger 114.

In this embodiment, top plunger 112 includes a tapered portion 122 that has a variable width along a portion of length 118 of spring probe. In particular, tapered portion 122 has a width that decreases from a first location 124 that is proximate to contact tip 116 to a second location 126 that is proximate to a shoulder 128 of shell 113. As a force 120 is applied to contact tip 116 of top plunger 112, length 118 of spring probe 110 is reduced. Tapered portion 122 of top plunger 112 interacts with features that form a cavity (not shown) of socket assembly 102, which causes contact tip 116 to move or deflect a pre-defined distance 130. The movement of contact tip 116 by pre-defined distance 130 scrubs the pads of IC package 104, removing oxidation and ensuring a reliable electrical connecting between spring probes 110 and the pads. This will be discussed in more detail below. Although FIG. 1 depicts a specific configuration of top plunger 112, shell 113, bottom plunger 114, tapered portion 122, and contact tip 116 for spring probe 110, spring probe 110 may have other configurations in other embodiments. For example, a tapered plunger structure may include single moving plunger probes and double moving plunger probes.

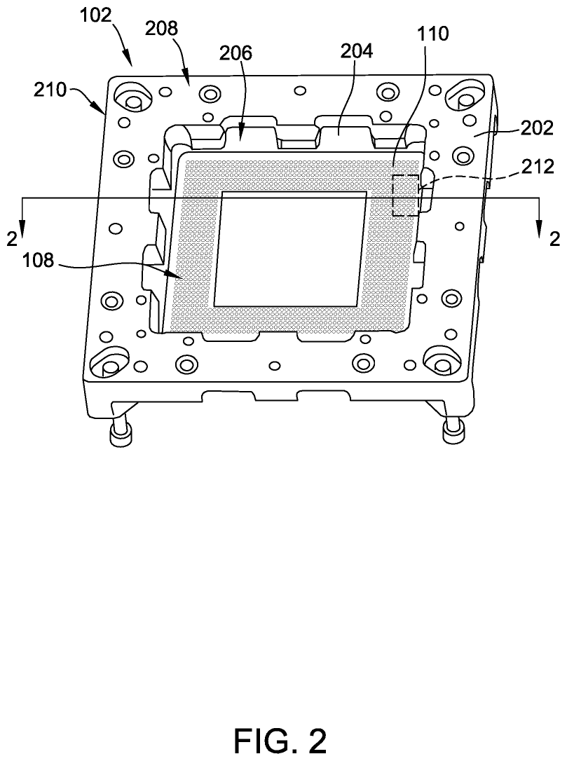

FIG. 2 depicts a perspective view of socket assembly 102 for IC test system 100 of FIG. 1 in an example embodiment. Socket assembly 102 in this embodiment includes a socket frame 202 that contacts a top cartridge 204 along a top surface 206 of top cartridge 204. Socket frame 202 and top cartridge 204 may be referred to as a main body in some embodiments. In other embodiments, top cartridge 204 individually is referred to as a main body.

FIG. 2 also depicts spring probes 110, which are arranged within opening 108 and partially extend into opening 108 from top surface 206 of top cartridge 204. Socket frame 202 and/or top cartridge 204 may be formed from metal, including aluminum, magnesium, titanium, zirconium, copper, iron, or alloys thereof. Portions of socket frame 202 may include insulation, such as aluminum oxide, which is electrically non-conductive. The insulating layer may be coated with a polytetrafluoroethylene (PTFE) coating. For example, a top surface 208 and sides of socket frame 202 around a perimeter 210 of socket assembly 102 may include insulation. In some embodiments, socket frame 202 and top cartridge 204 may be a single piece. When socket frame 202 and top cartridge 204 are a single piece, this combination may be referred to as a socket body. FIG. 2 also illustrates a region 212 of opening 108 that includes cavities for spring probes 110, which will be described in more detail below.

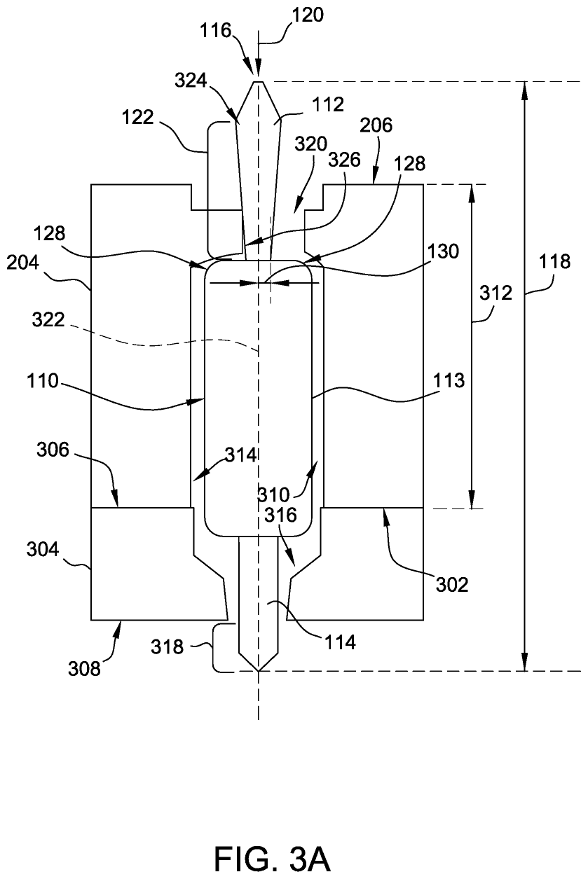

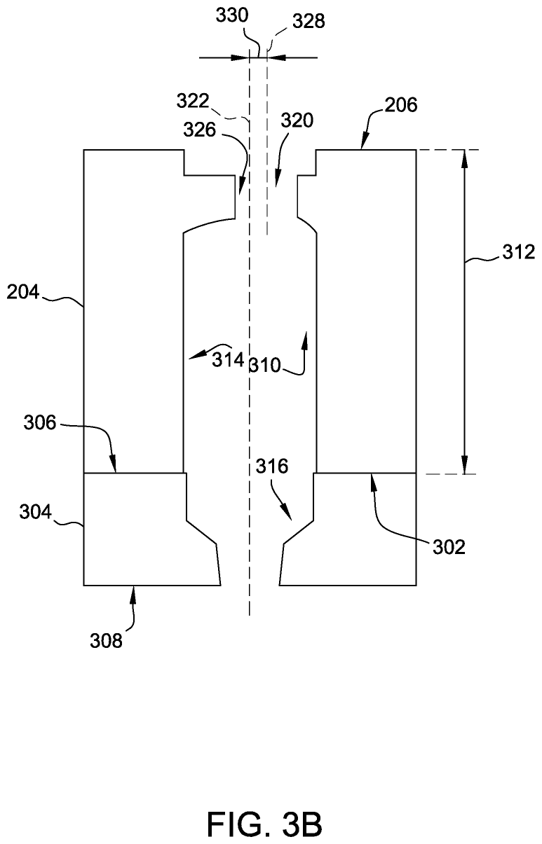

FIGS. 3A and 3B depict cross-sectional views of region 212 of socket assembly 102 along cut lines 2-2 of FIG. 2 in example embodiments. In the embodiment of FIG. 3A, top cartridge 204 includes a bottom surface 302 which opposes top surface 206 of top cartridge 204. A bottom cartridge 304 includes a top surface 306, which contacts bottom surface 302 of top cartridge 204. Bottom cartridge 304 further includes a bottom surface 308 which opposes top surface 306 of bottom cartridge 304. Bottom cartridge 304 may be formed from metal, including aluminum, magnesium, titanium, zirconium, copper, iron, or alloys thereof.

In the embodiment of FIG. 3A, spring probe 110 is disposed within cavity 310 that extend through a thickness 312 of top cartridge 204. Thickness 312 of top cartridge is defined as the distance between top surface 206 and bottom surface 302 of top cartridge 204. In some embodiments, cavity 310 includes an insulation layer along an inner wall 314 that electrically isolates spring probe 110 from top cartridge 204. In other embodiments, cavity 310 and spring probe 110 do not include insulation. For example, when spring probe 110 is used to couple a ground at PCB 106 to IC package 104, then spring probe 110 may not include insulation and instead, electrically couple top cartridge 204 to ground when socket assembly 102 is coupled to PCB 106 (see FIG. 1). In some embodiments, spring probe 110 includes insulation rather than cavity 310. For instance, when spring probe 110 is used for transmitting signals between IC package 104 and PCB 106, spring probe 110 may include insulation (not shown), which electrically isolates spring probe 110 from top cartridge 204. In other embodiments, neither spring probe 110 nor cavity 310 include insulation when top cartridge 204 is formed form an insulating plastic material.

In the embodiment of FIG. 3A, bottom cartridge 304 defines a probe retainer 316, which is aligned with cavity 310 in top cartridge 204. Probe retainer 316 prevents spring probe 110 from passing fully through cavity 310 and out of the bottom of socket assembly 102. In the embodiment of FIG. 3A, probe retainer 316 is partially open along bottom surface 308 of bottom cartridge 304, which allows a portion 318 of spring probe 110 to extend from bottom surface 308 of bottom cartridge 304 and contact PCB 106 when socket assembly 102 is mounted to PCB 106. In some embodiments, bottom cartridge 304 may be referred to as a main body probe cap. In some embodiments, probe retainers 316 and/or spring probe 110 may include insulation to prevent spring probe 110 from electrically shorting to bottom cartridge 304. In other embodiments, neither spring probe 110 nor probe retainer 316 include insulation when bottom cartridge 304 is formed form an insulating plastic material. Collectively, top cartridge 204 and bottom cartridge 304 may be referred to as a socket cartridge in some embodiments.

In this embodiment, top cartridge 204 defines an opening 320 in top surface of top cartridge 204 where contact tip 116 of top plunger 112 projects through such that contact tip 116, when IC package 104 is inserted into opening 108 of socket assembly 102 (see FIG. 1), contacts a pad on IC package 104. Opening 320 in this embodiment is offset relative to a centerline 322 of cavity 310. In some embodiments, opening 320 may be formed utilizing an offset hole formed or drilled into top surface 206 that extends from top surface 206 to cavity 310. Portions of the features that form opening in top cartridge 204 abut with shoulder 128 of shell 113 and prevents spring probe 110 from passing fully out of opening 320 in top cartridge 204.

When the pads of IC package 104 apply force 120 to spring probe 110, length 118 of spring probe 110 is reduced, and an outer surface 324 of tapered portion 122 slides along a contact surface 326 of opening 320. The interaction of outer surface 324 of tapered portion 122 and contact surface 326 of opening 320 displaces contact tip 116 pre-defined distance 130 away from centerline 322 of cavity 310, which scrubs away the oxidation on the pad of IC package 104 where contact tip 116 contacts the pad.

FIG. 3B depicts top cartridge 204 with spring probe 110 removed from cavity 310. In this view, top cartridge 204 defines a centerline 328 for opening 320, which has an offset 330 from centerline 322 of cavity 310. When spring probe 110 is compressed by force 120 (see FIG. 3A), tapered portion 122 interacts with contact surface 326 of top cartridge 204 based on offset 330 in opening 320 with respect to centerline 322 of cavity 310 to displace contact tip 116 of spring probe 110 pre-defined distance 130.

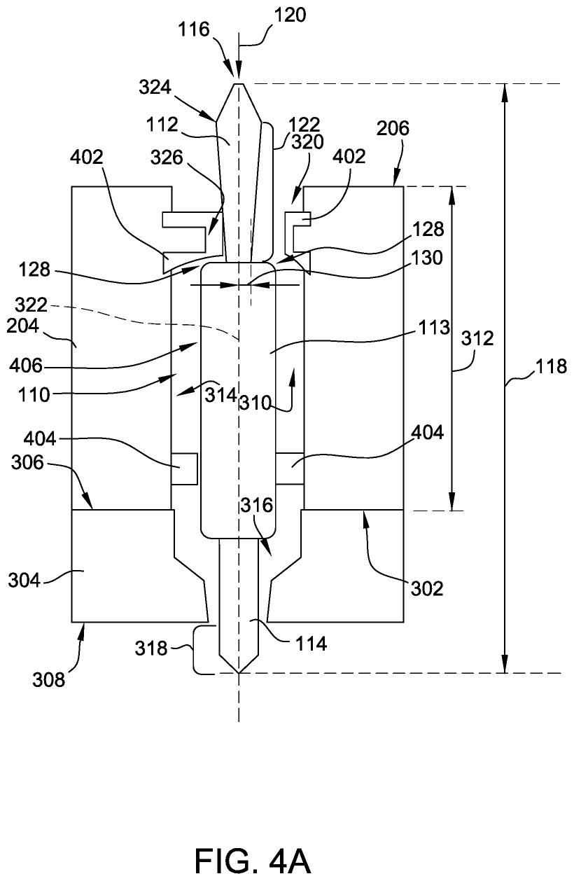

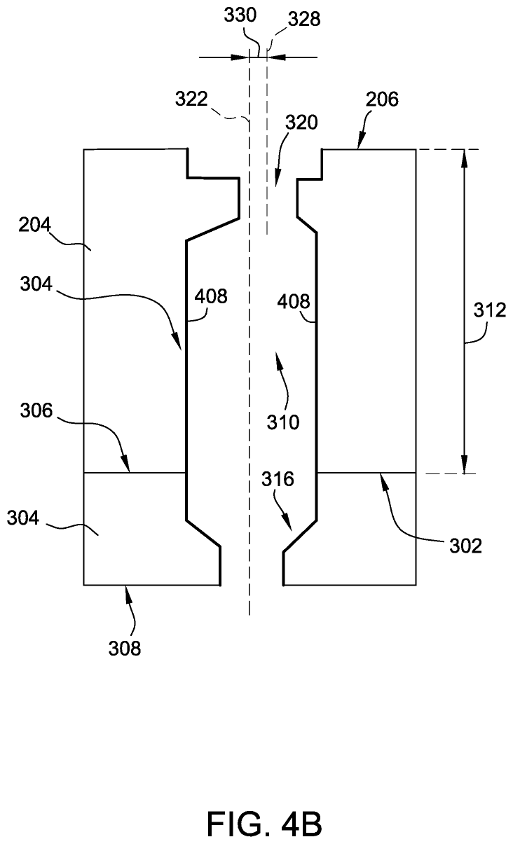

FIGS. 4A and 4B depict cross-sectional views of region 214 of socket assembly 102 along cut lines 2-2 of FIG. 2 in example embodiments. In the embodiment depicted in FIG. 4A, the features in top cartridge 204 that define opening 320 include an electrically insulating layer 402, which electrically isolates top cartridge 204 from spring probe 110 where tapered portion 122 of top plunger 112 extends through opening 320 and where shoulder 128 of shell 113 abuts with the features in top cartridge that define opening. In the embodiment of FIG. 4A, an electrically non-conductive ring 404 circumscribes an outer surface 406 of shell 113 and contacts inner wall 314 of cavity 310. Both electrically non-conductive ring 404 and insulation layer 402 operate to electrically isolate spring probe 110 from top cartridge 204 and bottom cartridge 304. In the embodiment depicted in FIG. 4B, top cartridge 204 and bottom cartridge 304 may be formed from metal, and the inside surfaces of cavity 310 of top cartridge 204 and probe retainer 316 of bottom cartridge 304 include an electrically insulating layer 408, which electrically isolates spring probe 110 (not shown in this view) from top cartridge 204 and bottom cartridge 304.

To assemble socket assembly 102, spring probes 110 are inserted into cavities 310 of top cartridge 204, bottom cartridge 304 is mounted to top cartridge 204, and socket frame 202 is placed over top cartridge 204 such that opening 108 of socket frame 202 exposes openings 320 of cavities 310 and contact tips 116 of spring probes 110. Socket assembly 102 may then be mounted to PCB 106, with portions 318 of spring probes 110 that protrude from bottom surface 308 of bottom cartridge 304 contacting PCB 106. IC package 104, when placed into opening 108, is electrically connected to PCB 106 via spring probes 110, which move or deflect pre-defined distance 130 based on offset 330 and tapered portion 122 as the pads of IC package 104 applies force 120 to compress spring probes 110 along their length 118.

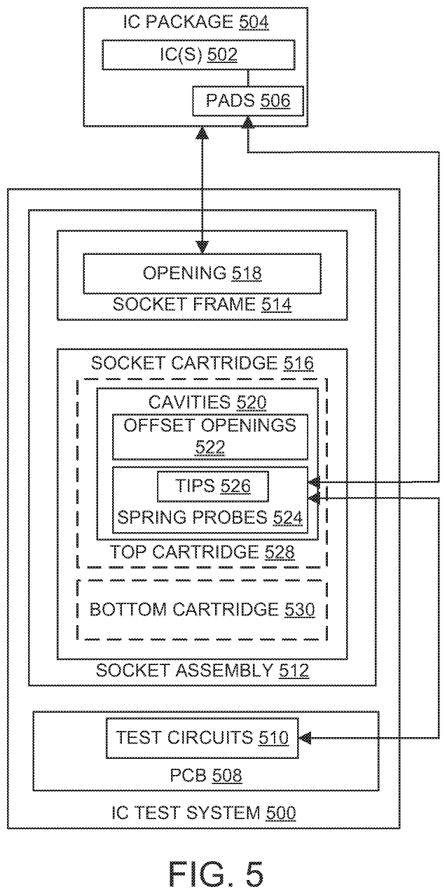

FIG. 5 is a block diagram of another IC test system 500 in example embodiment. In this embodiment, IC test system 500 is used to test one or more IC(s) 502, which are included within an IC package 504. IC package 504 may include, for example, any of the different types of packages previously described. IC(s) 502 are electrically connected to pads 506 of IC package 504, and pads 506 may be substantially planar.

In this embodiment, IC test system 500 includes a PCB 508, which includes test circuits 510. Test circuits 510 include any component, system, or device which performs functional tests on IC(s) 502. IC test system 500 further includes a socket assembly 512, which includes a socket frame 514 and a socket cartridge 516. Socket frame 514 includes any component, system, or device which defines an opening 518 that accepts IC package 504 for testing. Socket cartridge 516 includes any component, system, or device which defines cavities 520 that have offset openings 522 that are exposed by opening 518 in socket frame 514. Cavities 520 include spring probes 524, which partially extend through offset openings 522. When IC package 504 is inserted within opening 518 of socket frame 514, spring probes 524 electrically connect IC(s) 502 to test circuits 510 via pads 506 and contact tips 526 of spring probes 524. Offset openings 522 interact with spring probes 524 to partially scrub pads 506 when IC package 504 is inserted into opening 518 of socket frame 514. In this regard, spring probes 524 and/or offset openings 522 include any feature or combination features which displaces contact tips 526 substantially perpendicular to the direction of compression of spring probes 524, thereby resulting in, for example, a movement of contact tips 526 substantially lateral along a planar surface of pads 506. In some embodiments, socket cartridge 516 includes a top cartridge 528 that couples to a bottom cartridge 530.

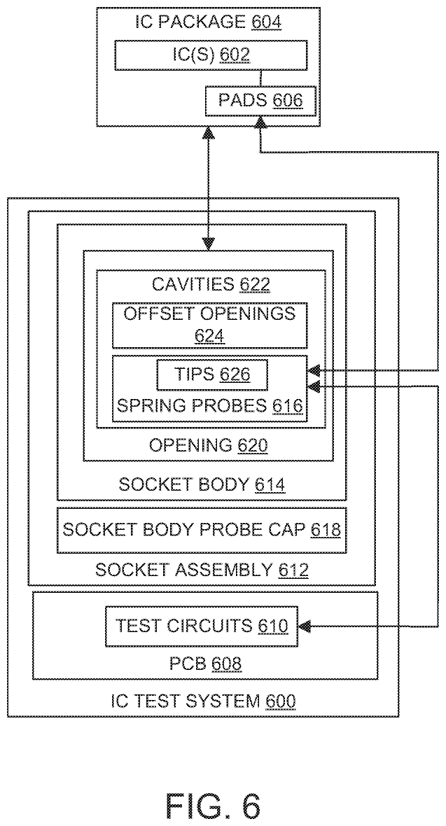

FIG. 6 is a block diagram of another IC test system 600 in example embodiment. In this embodiment, IC test system 600 is used to test one or more IC(s) 602, which are included within an IC package 604. IC package 604 may include, for example, any of the different types of packages previously described. IC(s) 602 are electrically connected to pads 606 of IC package 604, and pads 606 may be substantially planar.

In this embodiment, IC test system 600 includes a PCB 608, which includes test circuits 610. Test circuits 610 include any component, system, or device which perform functional tests on IC(s) 602. IC test system 600 further includes a socket assembly 612, which includes a socket body 614, spring probes 616, and a socket body probe cap 618.

Socket body 614 includes any component, system, or device which defines an opening 620 that accepts IC package 604 for testing. Socket body 614 further includes any component, system, or device which defines cavities 622 having offset openings 624 that are exposed by opening 620 in socket body 614. Cavities 622 include spring probes 616, which partially extend through offset openings 624. Spring probes 616 electrically connect IC(s) 602 to test circuits 610 via pads 606 and contact tips 626 of spring probes 616 when IC package 604 is inserted within opening 620 of socket body 614. Offset openings 624 interact with spring probes 616 to partially scrub pads 606 when IC package 604 is inserted into opening 620 of socket body 614. In this regard, spring probes 616 and/or offset openings 624 include any feature or combination features which displaces contact tips 626 substantially perpendicular to the direction of compression of spring probes 616, thereby resulting in, for example, a movement of contact tips 626 substantially lateral along a planar surface of pads 606. In this embodiment, socket body probe cap 618 secures spring probes 616 in place once spring probes 616 are inserted into cavities 622.

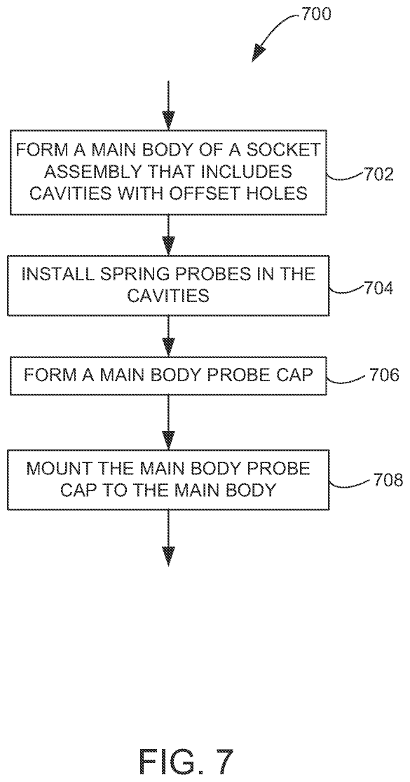

FIG. 7 depicts a flow chart of a method 700 of assembling a socket assembly for testing an IC of an IC package in an example embodiment. Method 700 begins by forming (702) a main body including a first surface and a second surface opposing the first surface, where the main body defines cavities that extend between the first surface and the second surface. The cavities are sized to receive spring probes, and the main body further defines openings at the first surface for the cavities that are offset relative to a centerline of the cavities. For example, with respect to FIG. 3A, top cartridge 204 includes cavity 310, and opening 320 in top surface 206 of top cartridge 204 is offset relative to centerline 322 of cavity 310.

Method 700 continues by installing (704) spring probes in the cavities, where the spring probes include a tapered portion and a contact tip that extend through the openings away from the cavities. For example, with respect to FIG. 3A, spring probe 110 is installed in cavity 310, and tapered portion 122 and contact tip 116 of spring probe 110 extends through opening 320 away from cavity 310.

Method 700 continues by forming (706) a main body probe cap. The main body probe cap includes a third surface and a fourth surface opposing the third surface. The third surface is configured to contact the second surface of the main body, and the main body probe cap includes probe retainers that extend between the third surface and the fourth surface. The probe retainers are aligned with the cavities and are sized to expose a portion of the spring probes at the fourth surface. For example, with respect to FIG. 3A, bottom cartridge 304 is formed. Bottom cartridge includes top surface 306 and bottom surface 308, and probe retainers 316. Probe retainer 316 is aligned with cavity 310 and is sized to expose portion 318 of spring probe 110 at bottom surface 308.

Method 700 continues by mounting (708) the main body probe cap to the main body. For example, with respect to FIG. 3A, bottom cartridge 304 is mounted to top cartridge 204, and bottom cartridge 304 secures spring probe 110 within cavity 310 while exposing portion 318 at bottom surface 308.

In some embodiments, method 700 forms the main body by forming though holes for the openings in the first surface of the main body that are offset relative to the centerlines of the cavities. For example, with respect to FIG. 3B, top cartridge 204 includes cavity 310, and opening 320 (a through hole in some embodiments) in top surface 206 of top cartridge 204 has offset 330 that is relative to centerline 322 of cavity 310.

In some embodiments, the main body defines a contact surface between the openings and the spring probes disposed within the cavities, and method 700 continues by forming electrically insulating material on the contact surfaces of the openings that electrically isolate the spring probes from the main body. For example, with respect to FIG. 4A, insulation layer 402 is formed on contact surface 326 of opening 320. In another example, with respect to FIG. 4B, insulation layer 408 is formed in the inner surfaces of cavity 310 and probe retainer 316.

In some embodiments, method 700 forms the main body by defining contact surfaces between the openings and the tapered portion of the spring probes that displaces the contact tips laterally with respect to the first surface and the second surface when the spring probes are compressed in length. For example, with respect to FIG. 3A, contact surface 326 in opening 320 defined by top cartridge 204 interacts with tapered portion 122 of spring probe 110 to displace contact tip 116 laterally with respect to top surface 206 of top cartridge 204 when spring probe 110 is compressed in length 118. When spring probe 110 is compressed in length 118, contact tip 116 moves pre-defined distance 130.

In some embodiments, method 700 forms the main body by forming a socket frame that defines an opening sized to receive the IC package. In this embodiment, method 700 continues by forming a top cartridge the defines the cavities and mounting the socket frame to the top cartridge by covering a portion of the top cartridge and exposing the cavities at the opening. For example, with respect to FIG. 2 and FIGS. 3A and 3B, socket frame 202 is formed (see FIG. 2), and top cartridge 204 is formed that defines cavity 310 (see FIGS. 3A and 3B). Socket frame 202 is mounted to top cartridge 204 (see FIG. 2)

An example technical effect of the apparatus and methods described herein includes one or more of: (a) ensuring a reliable electrical connection between spring probes and test pads by scrubbing the pads when the IC package is inserted into the test socket; and (b) preventing false testing failures due to oxidation on the pads of the IC package.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A socket assembly for testing an integrated circuit (IC) of an IC package, the socket assembly comprising:
a main body comprising a first surface and a second surface opposing the first surface, wherein the main body defines a cavity that extends between the first surface and the second surface, wherein the cavity is sized to receive a spring probe therein, and wherein the main body further defines an opening at the first surface for the cavity that is offset relative to a centerline of the cavity.

2. The socket assembly of claim 1, wherein:
the opening is defined by a through hole in the first surface of the main body that is offset relative to the centerline of the cavity.

3. The socket assembly of claim 1, wherein:
the main body defines a contact surface between the opening and a spring probe disposed within the cavity, and
the main body includes an electrically insulating layer on the contact surface that electrically isolates the spring probe from the main body.

4. The socket assembly of claim 3, further comprising:
a spring probe partially disposed within the cavity, wherein the spring probe comprises a tapered portion and a contact tip that extend through the opening away from the cavity; and
an electrically non-conductive ring circumscribing an outer surface of the spring probe that contacts an inner wall of the cavity.

5. The socket assembly of claim 1, further comprising:
a spring probe partially disposed within the cavity, wherein the spring probe comprises a tapered portion and a contact tip that extend through the opening away from the cavity.

6. The socket assembly of claim 5, wherein:
the main body defines a contact surface between the opening and the tapered portion of the spring probe, the contact surface configured to displace the contact tip laterally with respect to the first surface when the spring probe is compressed in length.

7. The socket assembly of claim 1, wherein:
the main body comprises a socket frame and a top cartridge that defines the cavity,
the socket frame defines an opening sized to receive the IC package, and
the socket frame is configured to cover a portion of the top cartridge and expose the cavity at the opening.

8. The socket assembly of claim 1, further comprising:
a main body probe cap comprising a third surface and a fourth surface opposing the third surface, wherein the third surface is configured to contact the second surface of the main body, and wherein the main body probe cap further comprises a probe retainer that extends between the third surface and the fourth surface, the probe retainer aligned with the cavity and sized to expose a portion of a spring probe at the fourth surface.

9. A method of assembling a socket assembly for testing an integrated circuit (IC) of an IC package, the method comprising:
forming a main body comprising a first surface and a second surface opposing the first surface, wherein the main body defines a cavity that extends between the first surface and the second surface, wherein the cavity is sized to receive a spring probe therein, and wherein the main body further defines an opening at the first surface for the cavity that is offset relative to a centerline of the cavity.

10. The method of claim 9, wherein forming the main body further comprises:
forming a through hole for the opening in the first surface of the main body that is offset relative to the centerline of the cavity.

11. The method of claim 9, wherein:
the main body defines a contact surface between the opening and a spring probe disposed within the cavity, and
the method further comprises forming an electrically insulating layer on the contact surface that electrically isolates the spring probe from the main body.

12. The method of claim 9, further comprising:
installing a spring probe partially disposed within the cavity, wherein the spring probe comprises a tapered portion and a contact tip that extend through the opening away from the cavity.

13. The method of claim 12, wherein forming the main body further comprises:
defining a contact surface between the opening and the tapered portion of the spring probe, the contact surface configured to displace the contact tip laterally with respect to the first surface when the spring probe is compressed in length.

14. The method of claim 9, wherein forming the main body further comprises:
forming a socket frame that defines an opening sized to receive the IC package;
forming a top cartridge that defines the cavity; and
mounting the socket frame to the top cartridge by covering a portion of the top cartridge and exposing the cavity at the opening.

15. The method of claim 9, further comprising:
forming a main body probe cap comprising a third surface and a fourth surface opposing the third surface, wherein the third surface is configured to contact the second surface of the main body, and wherein the main body probe cap further comprises a probe retainer that extends between the third surface and the fourth surface, the probe retainer aligned with the cavity and sized to expose a portion of a spring probe at the fourth surface.

16. A socket assembly for testing an integrated circuit (IC) of an IC package, the socket assembly comprising:
a plurality of spring probes, each comprising a tapered portion and a contact tip; and
a main body comprising a first surface and a second surface opposing the first surface, wherein the main body defines a plurality of cavities that extend between the first surface and the second surface, wherein each of the plurality of cavities is sized to receive one of the plurality of spring probes therein, wherein the main body further defines an offset hole at the first surface for each of the plurality of cavities, and wherein the tapered portion and the contact tip for each of the plurality of spring probes extend through the offset hole away from the first surface.

17. The socket assembly of claim 16, wherein:
contact between the tapered portion and a contact surface of the offset hole when the plurality of spring probes are compressed displaces the contact tip laterally with respect to a major plane of the first surface.

18. The socket assembly of claim 17, wherein:
the main body includes an electrically insulating layer on the contact surface that electrically isolates the plurality of spring probes from the main body.

19. The socket assembly of claim 16, wherein:
the main body comprises a socket frame and a top cartridge that defines the plurality of cavities,
the socket frame defines an opening sized to receive the IC package, and
the socket frame is configured to cover a portion of the top cartridge and expose the plurality of cavities at the opening.

20. The socket assembly of claim 16, further comprising:
a main body probe cap comprising a third surface and a fourth surface opposing the third surface, wherein the third surface is configured to contact the second surface of the main body, and wherein the main body probe cap further comprises a plurality of probe retainers that extend between the third surface and the fourth surface, each of the plurality of probe retainers aligned with one of the plurality of cavities and sized to expose a portion of one of the plurality of spring probes at the fourth surface.
